(19) United States
(12) Patent Application Publication
(10) Pub. No.: US 2020/0091163 A1
(43) Pub. Date: Mar. 19, 2020

(54) MEMORY DEVICE AND MANUFACTURING METHOD FOR THE SAME

(71) Applicant: MACRONIX INTERNATIONAL CO., LTD., Hsinchu (TW)

(72) Inventors: Yu-Wei JIANG, Hsinchu City (TW); Jia-Rong CHIOU, Zhubei City (TW)

(21) Appl. No.: 16/132,539

(22) Filed: Sep. 17, 2018

(51) Int. Cl. H01L 27/11556; H01L 27/11524

(52) U.S. Cl. CPC H01L 27/11556; H01L 27/11524

(57) ABSTRACT

A memory device and a manufacturing method for the same are provided. The memory device comprises a NAND memory string. The NAND memory string includes a U-shape channel, a first inversion gate electrode and a second inversion gate electrode. The U-shape channel includes a bottom channel surface, a first outer channel sidewall and a second outer channel sidewall. The bottom channel surface is between the first outer channel sidewall and the second outer channel sidewall opposing to the first outer channel sidewall. The first inversion gate electrode is electrically coupled to the U-shape channel and is disposed under bottom channel surface. The second inversion gate electrode is electrically coupled to the U-shape channel and is disposed outside the first outer channel sidewall, and separated from the first inversion gate electrode.

### BACKGROUND

### Technical Field

The disclosure relates to a semiconductor device and a manufacturing method for the same, and particularly to a memory device and a manufacturing method for the same.

### Description of the Related Art

As critical dimensions of devices in integrated circuits shrink toward perceived limits of manufacturing technologies, designers have been looking to techniques to achieve greater storage capacity, and to achieve lower costs per bit. Technologies being pursued include a NAND memory and an operation performed therefor.

### SUMMARY

The present disclosure relates to a memory device and a manufacturing method for the same.

According to an embodiment, a memory device is disclosed. The memory device comprises a NAND memory string. The NAND memory string comprises a U-shape channel, a first inversion gate electrode and a second inversion gate electrode. The U-shape channel UC comprises a bottom channel surface, a first outer channel sidewall and a second outer channel sidewall. The bottom channel surface is between the first outer channel sidewall and the second outer channel sidewall opposing to the first outer channel sidewall. The first inversion gate electrode is electrically coupled to the U-shape channel and is disposed on the bottom channel surface. The second inversion gate electrode is electrically coupled to the U-shape channel and is disposed outside the first outer channel sidewall, and separated from the first inversion gate electrode.

According to another embodiment, a manufacturing method for a memory device is disclosed. The manufacturing method comprises the following steps. A first inversion gate electrode is formed by using a first patterning process. A first stack structure is formed by using a second patterning process after the first patterning process. The first stack structure comprises gate electrode elements and insulating films stacked alternately. The gate electrode elements comprise a second inversion gate electrode. A channel element is formed on the first inversion gate electrode and the second inversion gate electrode.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1A illustrates a cross-section view of a memory device according to a concept in an embodiment.

FIG. 1B is a schematic drawing of a circuit of the memory device in FIG. 1A.

FIG. 2A illustrates a cross-section view of a memory device according to a concept in another embodiment.

FIG. 2B is a schematic drawing of a circuit of the memory device in FIG. 2A.

FIG. 3A illustrates a cross-section view of a memory device according to a concept in yet another embodiment.

FIG. 3B is a schematic drawing of a circuit of the memory device in FIG. 3A.

FIG. 4 illustrates a cross-section view of a memory device according to a concept in an embodiment.

FIG. 5A to FIG. 5H illustrate a manufacturing method for a memory device according to a concept in an embodiment.

FIG. 6 illustrates a step for a manufacturing method for a memory device according to a concept in an embodiment.

### DETAILED DESCRIPTION

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

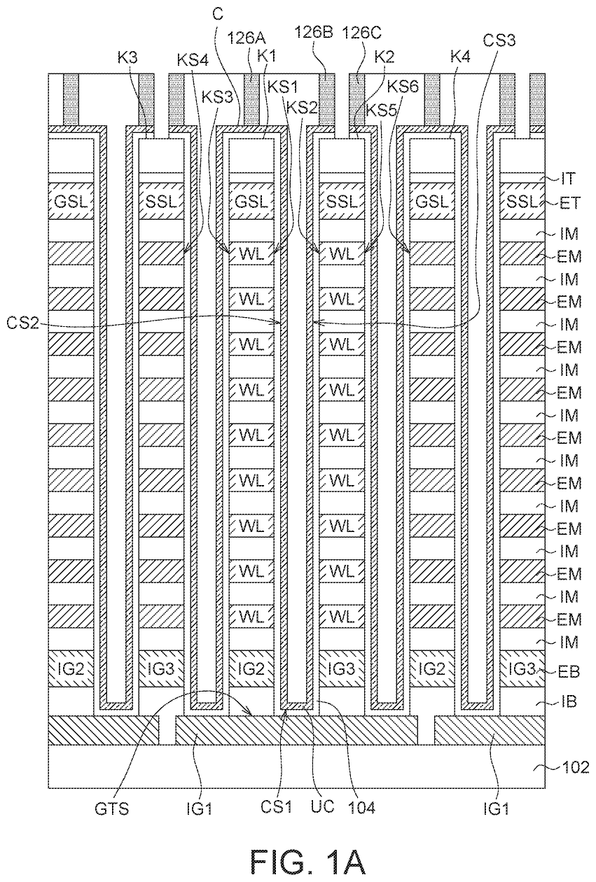

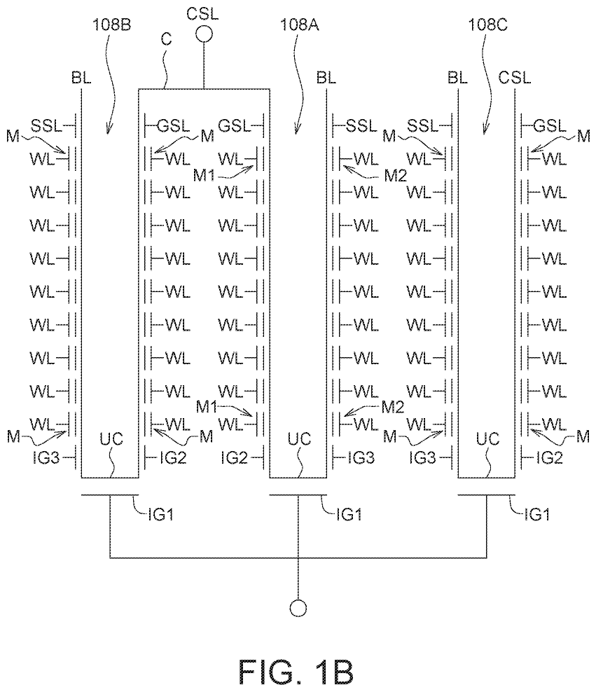

FIG. 1A and FIG. 1B are referred. FIG. 1A illustrates a cross-section view of a memory device according to a concept in an embodiment. FIG. 1B is a schematic drawing of a circuit of the memory device. In an embodiment, the memory device is a NAND flash memory device having a single gate vertical channel (SGVC) structure.

Referring to FIG. 1A, the memory device comprises a substrate 102, stack structures, a dielectric layer 104, a channel element C and a first inversion gate electrode IG1. The stack structures are on the substrate 102. For example, the stack structures comprise a first stack structure K1, a second stack structure K2, a third stack structure K3, a fourth stack structure K4, etc., separated from each other. The dielectric layer 104 may be formed on side walls and upper surfaces of the stack structures and on the first inversion gate electrode IG1. A portion of the dielectric layer 104 on a sidewall surface KS1 of the first stack structure K1, a sidewall surface KS2 of the second stack structure K2, and the upper surface (such as a top surface GTS) of the first inversion gate electrode IG1 has a U shape. The channel element C is formed over the dielectric layer 104. The channel element C comprises a U-shape channel UC on the sidewall surface KS1 of the first stack structure K1, the sidewall surface KS2 of the second stack structure K2, and the upper surface (such as the top surface GTS) of the first inversion gate electrode IG1.

Each of the stack structures may comprise gate electrode elements and insulating films stacked alternately. The gate electrode elements of a stack structure may comprise a bottom gate electrode element EB, a top gate electrode element ET, and intermediate gate electrode elements EM between the bottom gate electrode element EB and the top gate electrode element ET. The insulating films of a stack structures may comprise bottom insulating layer IB, a top insulating film IT, and intermediate insulating films IM between the insulating layer IB and the insulating film IT. In an embodiment, for example, for the first stack structure K1, the bottom gate electrode element EB may be functioned as a second inversion gate electrode IG2, the top gate electrode element ET may be used as a selection line such as a ground selection line GSL, and the other intermediate gate electrode elements EM may be used as word lines WL. For the second stack structure K2, the bottom gate electrode element EB may be used as a third inversion gate electrode IG3, the top gate electrode element ET may be used as a selection line such as a string selection line SSL, and the other intermediate gate electrode elements EM may be used as word lines WL. The first inversion gate electrode IG1 and the second inversion gate electrode IG2 may be separated from each other by the insulating layer IB of the first stack structure K1. The first inversion gate electrode IG1 and the third inversion gate electrode IG3 may be separated from each other by the insulating layer IB of the second stack structure K2.

Referring to FIG. 1A and FIG. 1B, the memory device comprises NAND memory strings, and comprises memory units M defined between the U-shape channel UC and the gate electrode elements EM used as the word lines WL. For example, the memory units M comprise memory units M1 and memory units M2 of a NAND memory string 108A. The memory units M1 of the NAND memory string 108A are defined between the gate electrode elements EM of the first stack structure K1 and the U-shape channel UC. The memory units M2 of the NAND memory string 108A are defined between the gate electrode elements EM of the second stack structure K2 and the U-shape channel UC. In other words, the memory cells M of the NAND memory string 108A comprise the memory cells M1 on the sidewall surface KS1 of the first stack structure K1, and the memory cells M2 on the sidewall surface KS2 of the second stack structure K2. The other NAND memory strings may are analogous to the NAND memory string 108A. For example, a NAND memory string 108B may comprise the memory units M defined on a sidewall surface KS3 of the first stack structure K1 and a sidewall surface KS4 of the third stack structure K3. A NAND memory string 108C may comprise the memory units M defined on a sidewall surface KS5 of the second stack structure K2 and a sidewall surface KS6 of the fourth stack structure K4, and so on.

The U-shape channel UC may comprise a bottom channel surface CS1, a first outer channel sidewall CS2 and a second outer channel sidewall CS3. The bottom channel surface CS1 is between the first outer channel sidewall CS2 and the second outer channel sidewall CS3 opposing to the first outer channel sidewall CS2. As shown in FIG. 1A, the bottom channel surface CS1 of the U-shape channel UC faces toward the substrate 102 (or the first inversion gate electrode IG1) The first inversion gate electrode IG1 is under the dielectric layer 104 under the bottom channel surface CS1. The first stack structure K1, comprising the ground selection line GSL, the word lines WL, and the second inversion gate electrode IG2, is outside the bottom channel surface CS2 of the U-shape channel UC. The second stack structure K2, comprising the string selection line SSL, the word lines WL, and the third inversion gate electrode IG3, is outside the second outer channel sidewall CS3 of the U-shape channel UC. The channel element C may be continuously extended from an upper surface of the first stack structure K1, through the first inversion gate electrode IG1, to be onto an upper surface of the second stack structure K2. In other words, the U-shape channel UC may be extended beyond opposing upper and lower surfaces of each of the gate electrode element EB, the gate electrode element ET, the gate electrode elements EM (comprising the ground selection line GSL, the word lines WL, the second inversion gate electrode IG2, the third inversion gate electrode IG3 and the string selection line SSL) of the first stack structure K1 and the second stack structure K2.

Conductive elements are on the channel element C on the upper surfaces of the stack structures. For example, a conductive element 126A is on the channel element C on the upper surface of the first stack structure K1. The conductive element 126A may be used as a common source line CSL. A conductive element 126B and a conductive element 126C are on the channel element C on the upper surface of the second stack structure K2, and are separated from each other. The conductive element 126B and the conductive element 126C may be used as bit lines BL respectively for different NAND memory strings.

Referring to FIG. 1A and FIG. 1B, the first inversion gate electrode IG1 is electrically connected to a portion of the U-shape channel UC between the second inversion gate electrode IG2 and the third inversion gate electrode IG3. The first inversion gate electrode IG1, the second inversion gate electrode IG2 and the third inversion gate electrode IG3 are electrically connected to a portion of the U-shape channel UC between the memory cells M1 on the sidewall surface KS1 of the first stack structure K1 and the memory cells M2 on the sidewall surface KS2 of the second stack structure K2.

Referring to FIG. 1A and FIG. 1B, in this embodiment, the first stack structure K1, the second stack structure K2, the third stack structure K3 and the fourth stack structure K4, and the dielectric layer 104 and the channel element C on the foregoing stack structures are disposed on the first inversion gate electrode IG1. Therefore, U-shape channels UC of the NAND memory string 108A, the NAND memory string 108B, and the NAND memory string 108C are electrically connected to a commonly used first inversion gate electrode IG1. In other words, in this embodiment, three NAND memory strings may be electrically connected a commonly used first inversion gate electrode IG1. In addition, in an erasing step for the memory device, the three NAND memory strings may be erased at the same time as a block unit. In embodiment, for example in a read operating step for the memory device, an inversion region may be induced in a lower portion of the U shape U-shape channel UC of the NAND memory string adjacent to the first inversion gate electrode IG1, the second inversion gate electrode IG2 and the third inversion gate electrode IG3 by applying voltages to the first inversion gate electrode IG1, the second inversion gate electrode IG2 and the third inversion gate electrode IG3 to increase charge carrier concentration in the inversion region. By which a resistance in a current path in the lower portion of the U-shape channel UC (or a resistance of the bit line BL) in an on-state of the memory device may be reduced. Therefore, a conductivity characteristic between opposing ends of the NAND memory string may be increased. The circuit for the other NAND memory strings may be understood according to the similar concepts.

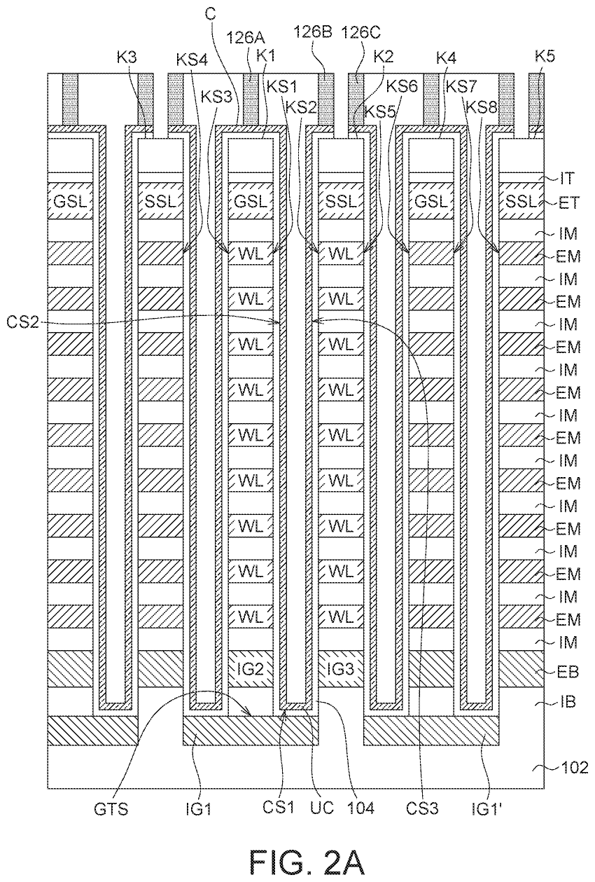

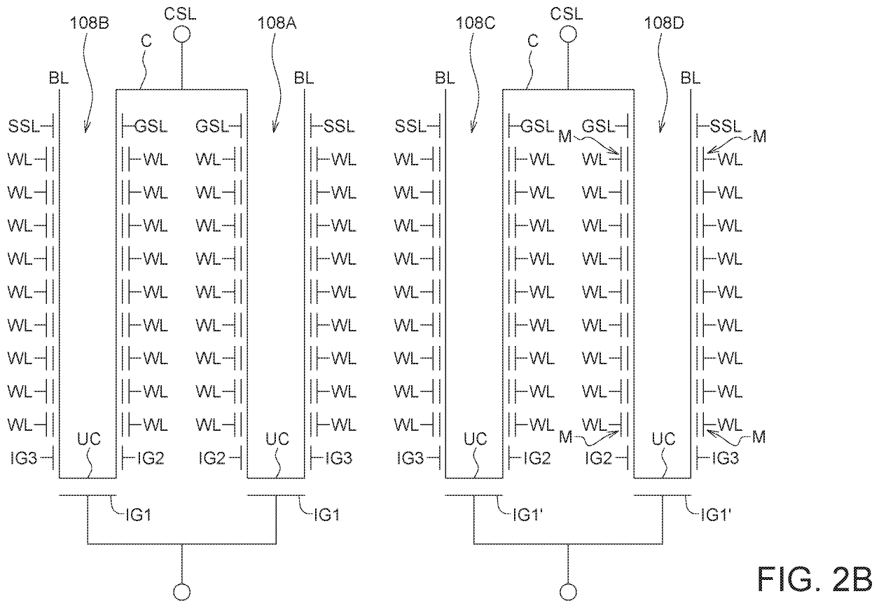

FIG. 2A and FIG. 2B are referred. FIG. 2A illustrates a cross-section view of a memory device according to a concept in another embodiment. FIG. 2B is a schematic drawing of a circuit of the memory device. The memory device referred to FIG. 2A and FIG. 2B is different from the memory device referred to FIG. 1A and FIG. 1B as the following description. In this embodiment, the first stack structure K1, and the dielectric layer 104 and the channel element C on the first stack structure K1, the second stack structure K2, and the third stack structure K3 are disposed on the first inversion gate electrode IG1. Therefore, U-shape channels UC of the NAND memory string 108A and the NAND memory string 108B are electrically connected to a commonly used first inversion gate electrode IG1. The circuit for the other NAND memory strings may be understood according to the similar concepts. For example, a NAND memory string 108D comprises the memory units M defined on a sidewall surface KS7 of the fourth stack structure K4 and defined on a sidewall surface KS8 of a fifth stack structure K5. The U-shape channels UC of the NAND memory string 108C and the NAND memory string 108D are electrically connected to another commonly used first inversion gate electrode IG1′. In other words, in this embodiment, two NAND memory strings may be electrically connected a commonly used first inversion gate electrode IG1. In addition, in an erasing step for the memory device, the two NAND memory strings may be erased at the same time as a block unit.

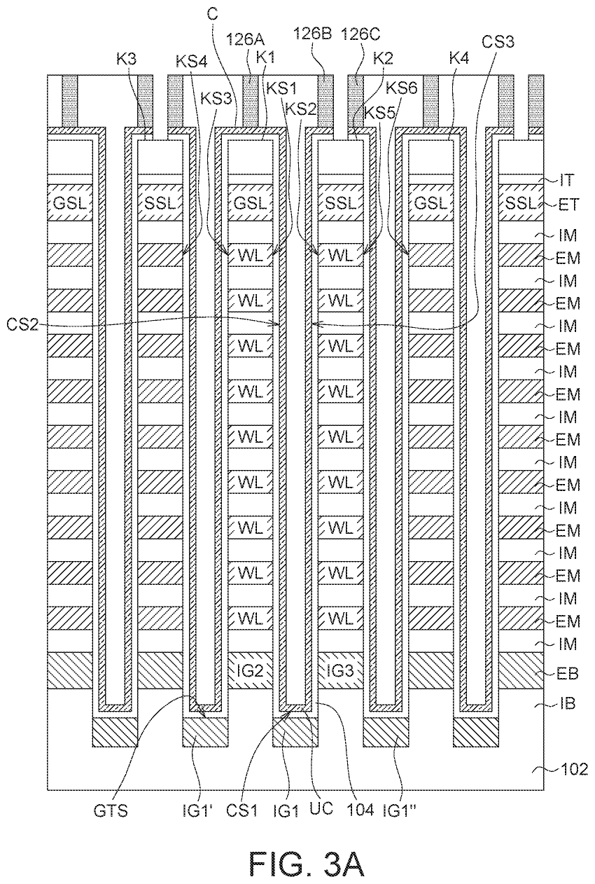

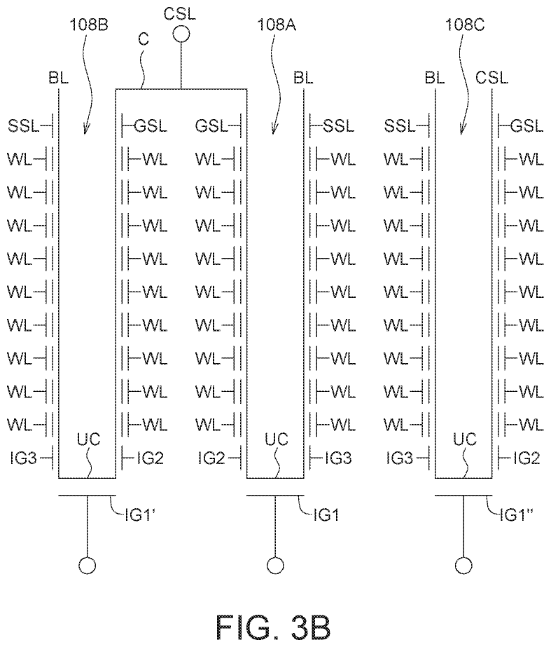

FIG. 3A and FIG. 3B are referred. FIG. 3A illustrates a cross-section view of a memory device according to a concept in yet another embodiment. FIG. 3B is a schematic drawing of a circuit of the memory device. The memory device referred to FIG. 3A and FIG. 3B is different from the memory device referred to FIG. 1A and FIG. 1B as the following description. The dielectric layer 104 and the U-shape channel UC between the first stack structure K1 and the second stack structure K2 may be disposed on the first inversion gate electrode IG1. In other words, the U-shape channel UC of the NAND memory string 108A is electrically connected to the first inversion gate electrode IG1. The circuit for the other NAND memory strings may be understood according to the similar concepts. For example, the U-shape channel UC of the NAND memory string 108B is electrically connected to the another first inversion gate electrode IG1′, and the U-shape channel UC of the NAND memory string 108C is electrically connected to yet another first inversion gate electrode IG1″, and so on. In an embodiment, the first inversion gate electrode IG1, the first inversion gate electrode IG1′ and the first inversion gate electrode IG1″ may be respectively electrically connected to voltage bias controlled independently. In other words, in this embodiment, the NAND memory strings may be electrically connected to the respective first inversion gate electrodes IG1, and the memory device may be erased with one of the NAND memory strings as one basic unit. In another embodiment, the first inversion gate electrode IG1, the first inversion gate electrode IG1′ and the first inversion gate electrode IG1″ separated from each other may be electrically connected to a common voltage through conductive elements.

In other embodiments, other amounts (for example an amount of 16, but not limited thereto) or combinations of the NAND memory strings may be electrically connected to a commonly used first inversion gate electrode IG1. In addition, the memory device may be erased with the NAND memory strings electrically connected the commonly used first inversion gate electrode IG1 as a basic block unit.

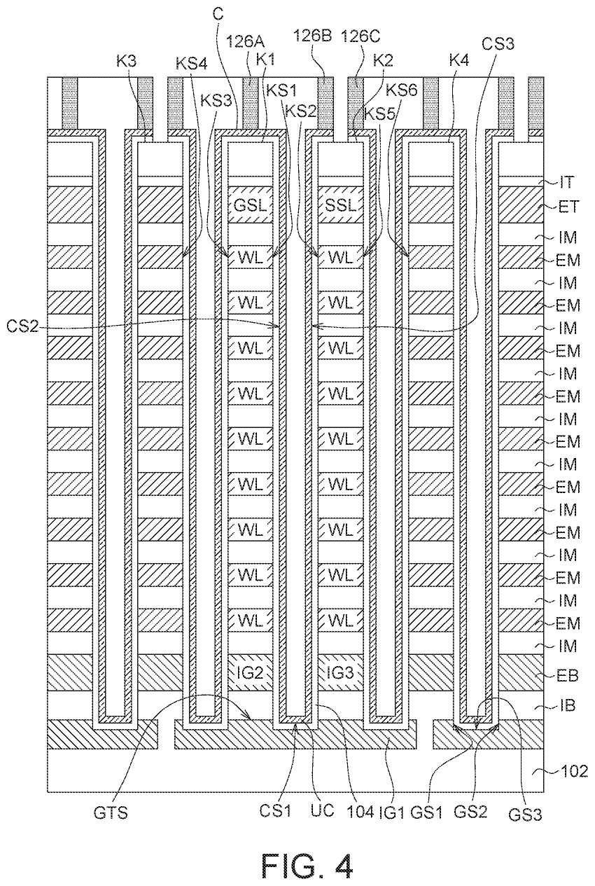

FIG. 4 illustrates a cross-section view of a memory device according to a concept in an embodiment, which is different from the memory device referred to FIG. 1A as the following description. In this embodiment, the dielectric layer 104 is extended beyond the top surface GTS of the first inversion gate electrode IG1 and is embedded into the first inversion gate electrode IG1. Therefore, the dielectric layer 104 is adjoined with an electrode surface GS1, an electrode surface GS2, and an electrode surface GS3 of the first inversion gate electrode IG1. The similar concepts may be applied in embodiments illustrated with referring to FIG. 2A and FIG. 3A, and so on.

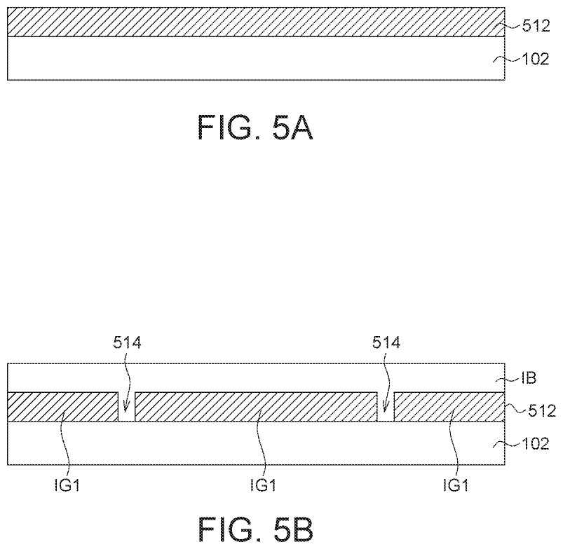

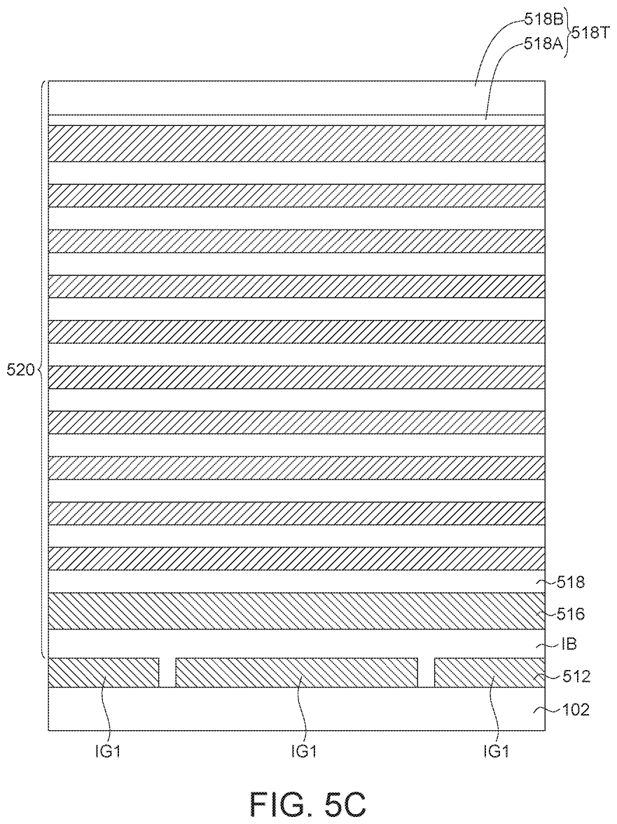

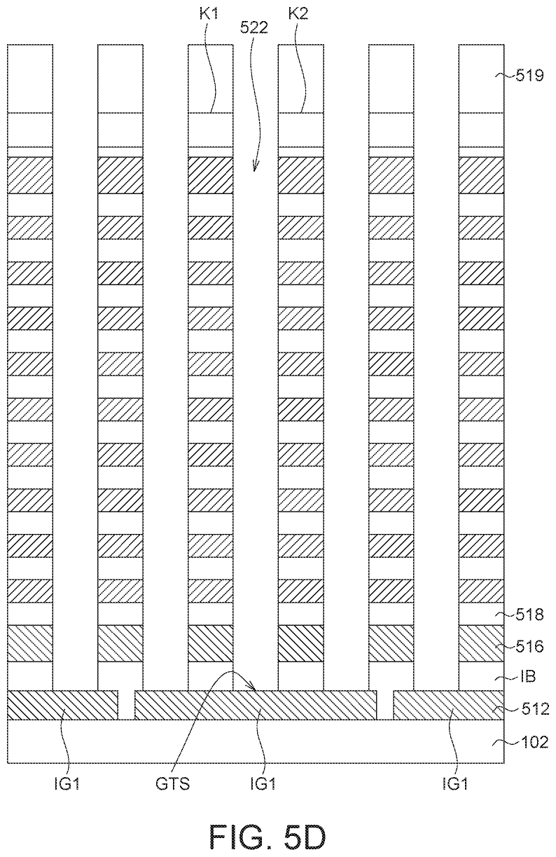

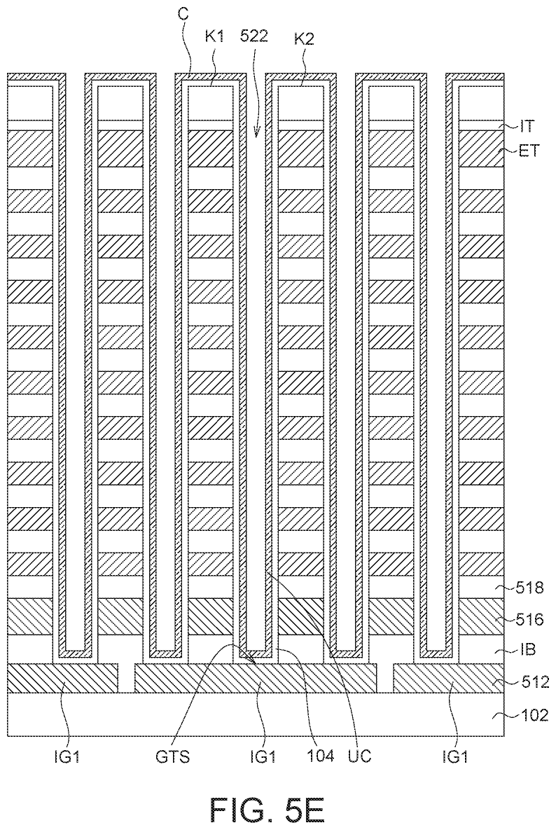

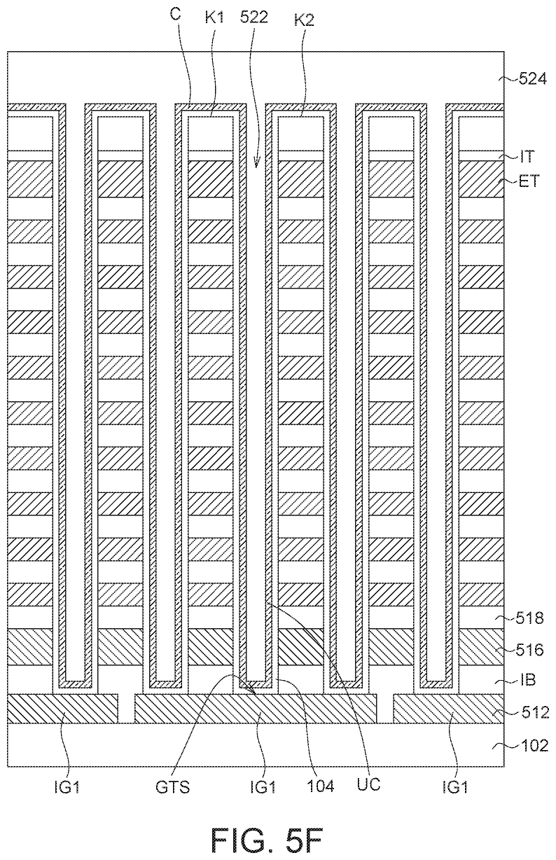

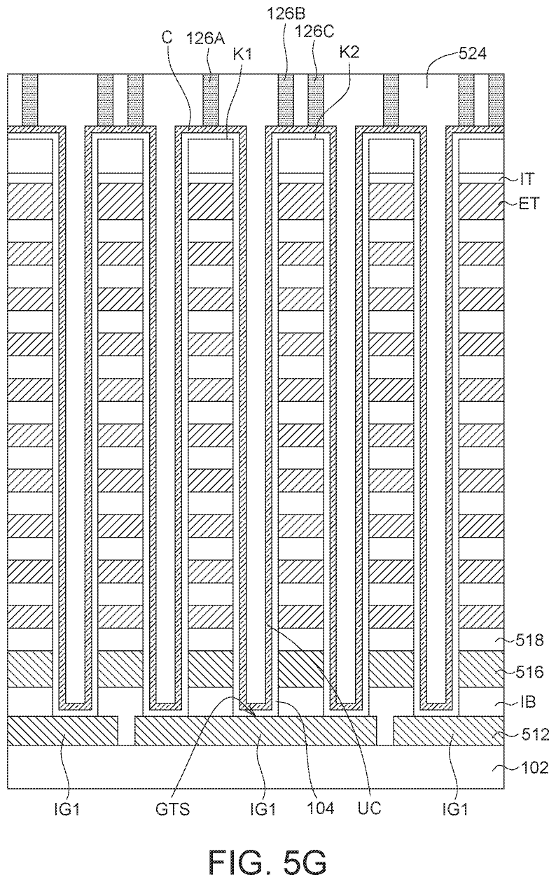

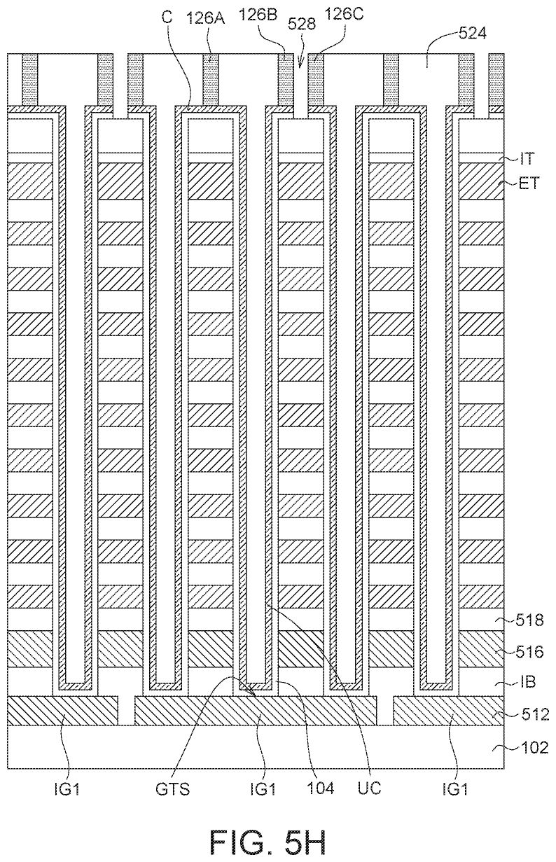

FIG. 5A to FIG. 5H illustrate a manufacturing method for a memory device according to a concept in an embodiment.

Referring to FIG. 5A, an electrode layer 512 is formed on the substrate 102. In an embodiment, the substrate 102 may comprise an insulating material, and the insulating may be formed on a semiconductor substrate. The semiconductor substrate comprises a silicon substrate, for example. In an embodiment, the insulating material may comprise an oxide, such as silicon oxide, and the like. The electrode layer 512 may comprise a conductive material, such as polysilicon, or a metal such as W, and so on. The electrode layer 512 may be formed by a deposition method such as a chemical vapor deposition method, a physical vapor deposition method, or other suitable methods.

Referring to FIG. 5B, a patterning process may be performed to the electrode layer 512 to form the first inversion gate electrodes IG1 separated from each other. The first inversion gate electrodes IG1 may be separated by an hole 514 formed by an etching step removing a portion of the electrode layer 512. The insulating layer IB may be formed to fill the hole 514 and on the upper surface of the first inversion gate electrode IG1. In an embodiment, the insulating layer IB may comprise an oxide such as silicon oxide. The insulating layer IB may be formed by a deposition method such as a chemical vapor deposition method, a physical vapor deposition method, or other suitable methods.

Referring to FIG. 5C, gate electrode elements 516 and insulating films 518 are stacked alternately on the insulating layer IB to form a stack structure 520. The insulating films 518 may comprise an oxide such as silicon oxide, or a nitride such as silicon nitride, and so on. In an embodiment, for example, the insulating films 518 may comprise a top insulating film 518T comprising a first insulating portion 518A and a second insulating portion 518B on the first insulating portion 518A. The first insulating portion 518A may comprise silicon oxide, and the second insulating portion 518B may comprise silicon nitride. The other insulating films 518 under the insulating film 518T may comprise silicon oxide. The gate electrode elements 516 may comprise a conductive material, such as polysilicon, or a metal such as W, etc. The gate electrode elements 516 may be formed by a deposition method such as a chemical vapor deposition method, a physical vapor deposition method, or other suitable methods.

Referring to FIG. 5D, a patterning process may be performed to the stack structure 520 to form the stack structures at the same time. For example, the stack structure comprises the first stack structure K1, the second stack structure K2, etc. The stack structure, such as the first stack structure K1 and the second stack structure K2 may be separated from each other by an opening 522 formed by an etching step of the patterning process removing a portion of the stack structure 520. In an embodiment, for example, a hard mask layer 519 may be formed on the stack structure 520, and the patterning process may comprise forming a patterned photoresist (not shown) on the hard mask layer 519 by using a lithographic etching process, transferring a pattern of the photoresist down into the hard mask layer 519, and then transferring the pattern of the hard mask layer 519 down into the stack structure 520. The patterning process of other suitable methods may be also used. In this embodiment, the etching step of the patterning process may use the first inversion gate electrode IG1 as an etching stop layer. In an embodiment, the etching step may stop at the timing detecting a signal of the first inversion gate electrode IG1 so as to form the opening 522 substantially the top surface GTS of the first inversion gate electrode IG1. The opening 522 also exposes sidewall surfaces of the insulating films and the gate electrode elements of each of the stack structures. The hard mask layer 519 may be removed after the patterning process.

Referring to FIG. 5E, the dielectric layer 104 is formed on the first inversion gate electrodes IG1 and the stack structures exposed by the opening 522. In an embodiment, the dielectric layer 104 may comprise a multilayer structure of oxide-nitride-oxide (ONO). In another embodiment, the dielectric layer 104 may comprise a multilayer structure of oxide-nitride-oxide-nitride-oxide (ONONO). The channel element C is formed on the dielectric layer 104. For example, the channel element C comprises a semiconductor material, such as a doped polysilicon material. The dielectric layer 104 and the channel element C may be formed by a deposition method such as a chemical vapor deposition method, a physical vapor deposition method, or other suitable methods. In other embodiments, the dielectric layer 104/the channel element C may be formed with other suitable materials/structure, and/or methods. Portions of the dielectric layer 104 and the channel element C in the opening 522 have a U shape. That is, the portion of the channel element C in the opening 522 is the U-shape channel UC.

Referring to FIG. 5F, an insulating material 524 is formed on the channel element C. The insulating material 524 may comprise an oxide such as silicon oxide, or other suitable insulating materials.

Referring to FIG. 5G, conductive elements are formed on the channel element C on the upper surfaces of the stack structures. For example, the conductive element 126A is formed on the channel element C on the upper surface of the first stack structure K1. The conductive element 126B and the conductive element 126C are formed on the channel element C on the upper surface of the upper surface of the second stack structure K2. In an embodiment, the conductive elements may be formed by using a lithographic etching step to remove a portion of the insulating material 524 to form a via hole exposing the channel element C, filling the via hole with a conductive material, and then performing a CMP process to flatten the conductive material. The conductive material may comprise a polysilicon, a metal such as W, Cu, etc., or a metal silicide, and the like.

Referring to FIG. 5H, a patterning process may be performed to form a trench 528 dividing channel element C into channel segments corresponding to the different NAND memory strings.

The manufacturing method for forming the memory device may be varied according to actual demands.

In an embodiment, for example, the step illustrated with FIG. 5G may be changed to form a single conductive film (not shown) on the channel element C on the upper surface of the first stack structure K1, and then pattern the conductive film into the conductive element 126B and the conductive element 126C separated by the trench 528 as shown in FIG. 5H.

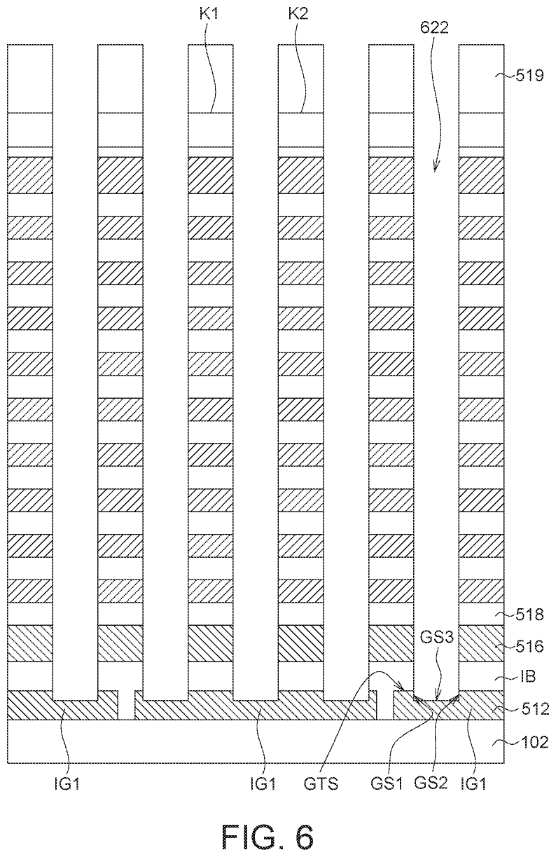

In another embodiment, the step illustrated with FIG. 5D may be replaced by a step illustrated with FIG. 6. In this embodiment, the etching step of the patterning process may stop at a certain time after the timing detecting the signal of the first inversion gate electrode IG1, with which the etching step may further proceed from the top surface GTS into an inside portion of the first inversion gate electrode IG1. Therefore, an opening 622 substantially exposing the electrode surface GS1, the electrode surface GS2, and the electrode surface GS3 of the first inversion gate electrode IG1 is formed. In an embodiment, a thickness of the first inversion gate electrode IG1 may be larger than a thickness of each of the gate electrode elements of the stack structures, and the thickness of the first inversion gate electrode IG1 is sufficient to avoid etching through a whole thickness of the first inversion gate electrode IG1 so as to ensure remain the first inversion gate electrode IG1 under a lower surface of the U shape U-shape channel UC to provide effect of reducing operating resistance of the memory device. Then, the step as illustrated with FIG. 5E and the subsequent steps after FIG. 5 may be performed to form the memory device as shown in FIG. 4, for example.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A memory device, comprising a NAND memory string, the NAND memory string comprising:
a U-shape channel comprising a bottom channel surface, a first outer channel sidewall and a second outer channel sidewall, the bottom channel surface being between the first outer channel sidewall and the second outer channel sidewall opposing to the first outer channel sidewall;
a first inversion gate electrode electrically coupled to the U-shape channel and disposed under the bottom channel surface; and
a second inversion gate electrode electrically coupled to the U-shape channel and disposed outside the first outer channel sidewall, and separated from the first inversion gate electrode.

2. The memory device according to claim 1, comprising a first stack structure, wherein the first stack structure comprises gate electrode elements and insulating films stacked alternately, the NAND memory string comprises memory cells defined between the gate electrode elements and the U-shape channel, wherein the second inversion gate electrode is electrically connected to a portion of the U-shape channel between the first inversion gate electrode and the memory cells.

3. The memory device according to claim 2, further comprising second stack structure, wherein the second stack structure comprises additional gate electrode elements and additional insulating films stacked alternately, wherein additional memory cells are defined between the additional gate electrode elements and the U-shape channel, wherein the first inversion gate electrode and the second inversion gate electrode are electrically connected to a portion of the U-shape channel between the memory cells and the additional memory cells.

4. The memory device according to claim 3, wherein the NAND memory string further comprises the additional memory cells.

5. The memory device according to claim 1, wherein the U-shape channel is extended beyond opposing surfaces of the second inversion gate electrode.

6. The memory device according to claim 1, further comprising an insulating layer, wherein the first inversion gate electrode and the second inversion gate electrode are separated from each other by the insulating layer.

7. The memory device according to claim 1, further comprising a dielectric layer between the U-shape channel and the first inversion gate electrode, and adjoined with the first inversion gate electrode.

8. The memory device according to claim 1, further comprising a third inversion gate electrode electrically coupled to the U-shape channel and disposed outside the second outer channel sidewall of the U-shape channel.

9. The memory device according to claim 8, wherein the U-shape channel is extended beyond opposing surfaces of the third inversion gate electrode.

10. The memory device according to claim 8, wherein the first inversion gate electrode is separated from the third inversion gate electrode.

11. The memory device according to claim 8, comprising a first stack structure, the first stack structure comprises gate electrode elements and insulating films stacked alternately, the NAND memory string comprises memory cells defined between the gate electrode elements and the U-shape channel, wherein the first inversion gate electrode and the second inversion gate electrode are electrically connected to a portion of the U-shape channel between the memory cells and the third inversion gate electrode.

12. The memory device according to claim 11, further comprising a second stack structure, wherein the second stack structure comprises additional gate electrode elements and additional insulating films stacked alternately, wherein additional memory cells are defined between the additional gate electrode elements and the U-shape channel, wherein the first inversion gate electrode, the second inversion gate electrode and the third inversion gate electrode are electrically connected to a portion of the U-shape channel between the memory cells and the additional memory cells.

13. A manufacturing method for a memory device, comprising:
forming a first inversion gate electrode by using a first patterning process;
forming a first stack structure by using a second patterning process after the first patterning process, wherein the first stack structure comprises gate electrode elements and insulating films stacked alternately, the gate electrode elements comprise a second inversion gate electrode; and
forming a channel element on the first inversion gate electrode and the second inversion gate electrode.

14. The manufacturing method for the memory device according to claim 13, further comprising forming a second stack structure, wherein the first stack structure and the second stack structure are formed at the same time, and the second stack structure comprises additional gate electrode elements and additional insulating films stacked alternately, the additional gate electrode elements comprise a third inversion gate electrode.

15. The manufacturing method for the memory device according to claim 13, wherein an opening is formed through the second patterning process, the second inversion gate electrode has only a sidewall surface exposed by the opening.

16. The manufacturing method for the memory device according to claim 13, wherein an opening is formed by the second patterning process, and the first inversion gate electrode is exposed by the opening.

17. The manufacturing method for the memory device according to claim 16, wherein the first inversion gate electrode has only a top surface exposed by the opening.

18. The manufacturing method for the memory device according to claim 16, wherein an upper surface and a sidewall surface of the first inversion gate electrode are exposed by the opening.

19. The manufacturing method for the memory device according to claim 16, wherein the channel element is formed in the opening.

20. The manufacturing method for the memory device according to claim 13, further comprising forming a dielectric layer on the first inversion gate electrode and the second inversion gate electrode, wherein the channel element is formed on the dielectric layer.
